(19) United States
(12) Patent Application Publication
(10) Pub. No.: US 2006/0270244 A1
(43) Pub. Date: Nov. 30, 2006

(54) Method of fabricating a structure with an oxide layer of a desired thickness on a Ge or SiGe substrate

(76) Inventors: Nicolas Daval, Grenoble (FR); Yves-Mathieu Le Vaillant, Crolles (FR)

Correspondence Address: WINSTON & STRAWN LLP, 1700 K STREET, N.W., WASHINGTON, DC, 20006, US

(21) Appl. No.: 11/207,069

(22) Filed: Aug. 17, 2005

(30) Foreign Application Priority Data
May 27, 2005 (FR) 0505358

(51) Int. Cl. H01L 21/31

(52) U.S. Cl. 438/758

(57) ABSTRACT

The present invention provides a method of forming a structure produced from semiconductor materials with the structure having a substrate layer and an insulating layer, and the method including the steps of creating the insulating layer involving constituting an oxidizable layer on the substrate layer and oxidizing the oxidizable layer. The method includes the steps of providing a thin elemental insulating layer at a mean thickness of 20 nm or less upon a substrate layer; providing an oxidizable layer upon the insulating layer; thermally oxidizing the oxidizable layer so that the combination of the oxidized oxidizable layer and the thin elemental insulating layer provides a desired thickness of the insulating layer of the structure.

### BACKGROUND

The present invention relates in general to fabricating structures from materials selected from semiconductor materials, for applications in microelectronics, optics, or optronics.

More precisely, the invention concerns a method of constituting a structure produced from semiconductor materials and comprising a substrate layer and an oxide layer, the method comprising a step of creating the oxide layer involving constituting an oxidizable layer on the substrate layer and oxidizing the oxidizable layer.

There are known methods for constituting a structure comprising a substrate layer and an oxide layer. For example, direct oxidation of a substrate layer formed from silicon to form an oxide layer in the surface layer of the substrate layer is known. This “direct” oxidation consists of heat treating the substrate layer to oxidize the surface region of the substrate layer. While direct oxidation is possible in the case of silicon, however, it does not constitute a satisfactory solution in the case of a substrate layer produced from a material such as germanium (Ge) or silicon germanium (SiGe). Indeed, for such materials, direct oxidation generates a layer of oxide on the surface of the substrate layer which has a free surface that is irregular. This constitutes a disadvantage, when either the oxide layer is then destined to be covered with a covering layer so that it can be buried in the structure, or it is destined to remain on the surface of the structure.

Further, thermal oxidation causes segregation of Ge from the silicon oxide (SiO₂) layer which is forming, thus producing, between the remaining intact SiGe and the SiO₂, an intermediate layer which is progressively depleted in silicon (Si) and which has a thickness that increases throughout oxidation, thereby slowing formation of the SiO₂ layer and limiting its thickness. Furthermore, the intermediate layer causes the appearance of dislocations due to the internal stresses to which it is subjected.

Depositing the oxide layer by covering the substrate layer is also known. Such deposition generally employs CVD (chemical vapor deposition), PECVD (plasma enhanced chemical vapor deposition), or LPCVD (low pressure chemical vapor deposition) type techniques. However, it can be expected that the electrical quality of a deposited oxide will be lower than that of a thermal oxide. Thus:

the precursors and radicals used may be found in the oxide layer due to incomplete decomposition;

an accumulation of electric charges is observed in the bulk and at the interface between the substrate layer and the oxide layer, which may perturb the electrical function of the structure;

adhesion between the substrate layer and the oxide layer may be problematic.

Finally, those problems are more prominent when the deposition temperature is low. However, depositing oxide on SiGe with a high concentration of Ge (>20%) happens to suffer from temperature limitations due to problems with material instability. Thus, for pure Ge, the deposition temperature will typically be limited to about 650° C., while it may reach 1200° C. for SiGe alloys with a low Ge concentration.

That type of deposition is therefore unsatisfactory, in particular for materials which are unstable at high temperatures.

Further, U.S. Pat. No. 6,352,942 discloses a method allowing a layer of SiO₂ to be constituted with a thickness of the order of 35 nanometers (nm) on a Ge substrate layer. That method involves covering a Ge substrate layer with a layer of Si then oxidizing the Si layer. It produces a structure comprising a layer of SiO₂ on a layer of Ge. However, such a method is limited in practice to constituting layers of oxide with a very limited thickness.

Forming too thick a layer of Si creates a high dislocation density, substantially reducing the dielectric properties of the oxide layer. In practice, it cannot be used on an industrial scale to produce oxide layers with a thickness which is of the order of one or more hundred nanometers. However, constituting such relatively thick oxide layers may be desirable—especially when constituting a sufficiently insulating buried oxide layer in a structure.

Further, industrial constraints require that the oxidation period be minimized. However, forming thick layers of thermal oxide takes a long time, especially since the oxidation rate drops substantially beyond a certain oxidation depth. The oxidation rate varies depending on whether the oxidation front is less than or greater than a limiting oxidation thickness:

if it is less, the oxidation rate is substantially constant; the oxidation rate is thus linear;

if it is greater, the oxidation rate drops off ever more steeply, the oxidation rate is thus asymptotic and the oxidation period becomes extremely long once the thickness has become substantial.

From an industrial viewpoint, then, the SiO₂ thickness must be limited to reduce costs, although a thick oxide layer would be preferable to guarantee more reliable electrical products.

U.S. Pat. No. 4,604,304 proposes producing a thick (1200 nm) oxide layer on a substrate layer of Si by alternating the operations of depositing crystalline or amorphous silicon and oxidation. The thickness of each deposited Si layer is less than the limiting thickness below which oxidation occurs in a linear manner. The oxidation period is thus substantially reduced compared with oxidizing a single layer of Si with a thickness identical to the total thickness of the set of oxidized layers. Forming such a thick SiO₂ layer may then become industrially acceptable. However, such operations to oxidize thick layers cause oxidation inhomogeneities, which mean that some parts of the oxidation fronts reach the substrate layer before other parts. As a result, the final thickness of the oxide is inhomogeneous, the oxide-semiconductor interface is not flat, and the electrical properties at the interface are degraded. Thus, the interface quality produced by that technique is not sufficiently high.

It therefore appears that known methods have their limitations. The general aim of the invention is to overcome those limitations.

### SUMMARY OF THE INVENTION

A specific goal of the present invention is to form a thick oxide layer in a predetermined structure which has a high quality interface with the subjacent substrate layer. Another aim of the invention, then, is to be able to produce layers of oxide on a substrate layer formed from a material such as Ge or SiGe. A further particular aim of the invention is to be able to produce the oxide layer with a thickness of the order of one or more hundred nanometers, in particular to constitute structures in which the oxide layer will be buried. Furthermore, the invention can envisage the production of oxide layers of any desired thickness. A further particular aim of the invention is to be able to produce layers of oxide as mentioned above at a production rate which is compatible with industrial production demands.

The invention proposes a method of constituting a structure produced from semiconductor materials and comprising a substrate layer and an insulating layer, the method comprising a step of creating the insulating layer involving constituting an oxidizable layer on the substrate layer and oxidizing the oxidizable layer, wherein the step of creating the insulating layer comprises:

a) constituting a thin elemental insulator layer on the substrate layer to produce a final thickness not exceeding a mean of 20 nm;

b) constituting an oxidizable layer by covering the thin elemental insulator layer; and

c) thermally oxidizing the oxidizable layer;

so that the combination of the layers formed constitutes the insulating layer of the structure, the insulating layer of the structure having the desired thickness.

Other characteristics of the method are as follows:

the thin elemental insulator layer is constituted by depositing an insulating material;

the thin elemental insulator layer which is deposited does not exceed 10% of the total thickness of the insulating layer formed at the end of step c);

the substrate layer is covered with a thin elemental oxidizable layer and the thin elemental insulator layer is constituted by thermal oxidation of at least a portion of the thin elemental oxidizable layer at an oxidation temperature which is sufficiently low not to substantially alter the intrinsic properties of the material constituting the substrate layer;

the oxidation temperature of the thin oxidizable layer is of the order of 500° C. to 700° C.;

the oxidation temperature of the thin oxidizable layer is in the range from about 700° C. to about 900° C.;

oxidizing the thin elemental oxidizable layer employs a gaseous oxide of nitrogen in addition to oxygen;

oxidizing the thin elemental oxidizable layer is carried out to incorporate 1.5% to 2% of nitrogen;

the thin elemental oxidizable layer is thinner than the oxidizable layer constituted during step b);

the method further comprises epitaxy of the thin elemental oxidizable layer covering the substrate layer, optionally carried out in situ following epitaxy of the surface layer of the substrate layer;

the substrate layer comprises a surface portion of Si₁₋ₓGeₓ, with x in the range 0 (included) to 1 (included);

the substrate layer is formed from Si₁₋ₓGeₓ, with x in the range 0 (included) to 1 (included);

the thin elemental oxidizable layer is constituted by the same material as that constituting the surface portion of the substrate layer;

the thin elemental oxidizable layer is formed from silicon;

the thin elemental oxidizable layer is formed from amorphous silicon;

the oxidizable layer constituted during step b) is formed from silicon;

the oxidizable layer constituted during step b) is formed from amorphous silicon;

the oxidizable layer is constituted during step b) so that its final thickness is in the range from about 50 nm to about 100 nm;

the oxidizable layer constituted during step b) is produced by LPCVD deposition between about 550° C. and about 580° C.;

the operations of steps b) and c) are repeated in succession for the desired number of times;

following the step of creating the insulating layer of the structure, the method comprises a step of covering the insulating layer with a covering layer, the insulating layer thus being buried.

### BRIEF DESCRIPTION OF THE DRAWING FIGURES

Other characteristics, aims and advantages of invention will be described below with reference to the accompanying drawings:

FIGS. 1 to 5 represent the various steps of a method of the invention for producing a structure including a thick oxide layer.

### DETAILED DESCRIPTION OF THE PREFERRED EMBODIMENTS

The method of the invention comprises forming a thick oxide layer in a structure comprising one or more semiconductor material(s). The term “thick” oxide layer means an oxide layer with a thickness of more than about 100 nm, for example a layer that is 200 nm, 500 nm or 1000 nm thick. This thick oxide layer is produced in two phases in succession:

Phase 1: forming a thin insulating layer; the term “thin layer” means a layer that is a few nanometers thick, not exceeding a mean of about 20 nm;

Phase 2: forming at least one thick oxide layer on the thin insulating layer.

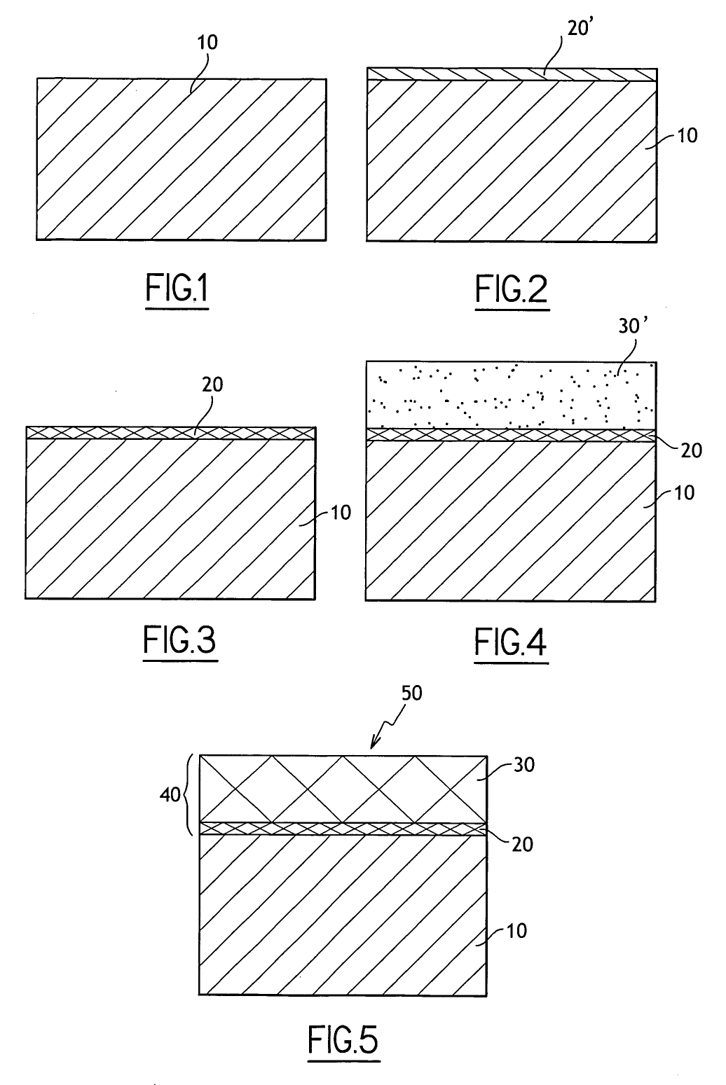

FIG. 1 shows a substrate layer 10 which is simply termed below “substrate 10” from which the layers are formed.

The substrate 10 may be formed from bulk crystalline material, for example germanium obtained by Czochralski pulling. the substrate 10 may also have a multilayered crystalline structure obtained, for example, by epitaxy, such as a relaxed SiGe/SiGe buffer layer/Si substrate structure in which the buffer layer may be a layer with a graduated concentration of germanium. It may also be a multilayered crystalline structure obtained by steps for bonding and transfer of layers, optionally followed by chemical, mechanical (polishing), or thermal treatment methods.

The detailed description below discloses the non limiting case of a substrate 10 comprising at least a surface portion of Si₁₋ₓGeₓ (0≦x≦1). The surface of the structure may optionally be treated to reduce its surface roughness and to reduce its dislocation density due to stress relaxation, for example by polishing. Then, in the oxide formation phase 1, a thin elemental insulator layer is constituted at the surface of the substrate 10.

In a first embodiment, the thin insulator elemental layer is produced by depositing SiO₂ or Si₃N₄ at a temperature that is lower than the limiting temperature beyond which a material contained in the substrate 10 will become unstable. If the substrate 10 contains a layer of germanium, oxide or Si₃N₄ deposition is advantageously carried out at a temperature of less than about 650° C. In particular, the Si₃N₄ deposited, for example, using a deposition technique such as LPCVD or PECVD, can block oxygen diffusion from the thick oxide layer which will then be formed (in phase 2) and can thus protect the subjacent substrate layer 10. The precursors used to deposit the oxide may be silane/oxygen, dichlorosilane/oxygen or tetraethyloxysilane (TEOS).

The thin oxide layer is deposited so as to produce a final simple “film” with a few nanometers of SiO₂ at the surface of the substrate 10, not exceeding a mean of about 20 nm.

The thickness is selected so as to be sufficiently low not to encounter the old problem linked to depositing oxide on SiGe materials with a high germanium concentration (as discussed above). To this end, the selected thickness does not exceed 10% of the total thickness of the complete oxide layer which is to be formed.

In a second embodiment, this first oxide formation phase is carried out in two successive operations, as shown in FIGS. 2 and 3. In a first operation, a thin elemental oxidizable layer 20′ constituted by a semiconductor material is formed on the substrate 10.

Preferably, the deposition technique employed is epitaxy. It is optionally carried out in situ on the substrate 10 immediately after forming the surface crystalline portion of the substrate 10, to minimize the charge density at the interface. Before the epitaxy, it may be decided that the surface of the substrate 10 should be cleaned using known cleaning means. In particular, it may be decided that all traces of native oxide on the surface of the substrate 10 should be removed.

The thin layer 20′ may be deposited using CVD techniques. The epitaxy parameters are selected to constitute a thin layer 20′ a few nanometers thick, not exceeding a mean of 20 nm, to obtain a layer with a thickness not exceeding 20 nm following oxidation.

The thin elemental oxidizable layer 20′ may be formed from crystalline or amorphous silicon, from Si_{1-y}Ge_{y} (with y in the range of 0 to 1), or from another material which is compatible with crystalline growth of the right quality considering the lattice parameter of the surface layer of the substrate 10. In particular, it may be decided to constitute a thin elemental oxidizable layer 20′ from Si₁₋ₓGeₓ formed at the same time or contiguously with the surface layer of Si₁₋ₓGeₓ of the subjacent substrate 10.

Referring now to FIG. 3, a second operation consists of at least partial oxidation of the thin elemental oxidizable layer 20′ to constitute a thin oxide layer 20 a few nanometers thick, not exceeding a mean of about 20 nm. This oxidation, which may be dry or wet, is carried out to provide adequate control of the advance of the oxidation front so that it does not become too inhomogeneous and thus susceptible of reducing the quality of the interface with the substrate 10. The oxidation parameters, in particular temperature, are advantageously selected so that oxidation occurs at a rate allowing proper control of the duration of this step. Thus, it is preferable to use low temperature oxidation, i.e. between about 700° C. and about 900° C. (in particular in the case of dry oxidation). Thus, the oxidation period, and hence the oxidized thickness, may be controlled more precisely; it may be in the range from a few minutes to a few hours.

Clearly, the oxidation must also take into account the potential instability of materials which may contain the substrate 10 at the selected temperatures. In particular, oxidation must be carried out so that the material(s) of the substrate 10 remain stable at the temperatures selected for oxidation. For better control of the method, and always with a care to reducing the oxidation rate, it is also possible to elect to dilute the oxygen in a neutral atmosphere (Ar, N) (for example 1% O₂ in 99% Ar). Finally, because a very thin oxidizable layer 20′ has been selected, oxidation is carried out over a very small depth and risks of inhomogeneities in the oxidation front are reduced in all cases.

Optionally, the oxidation may remain partial, in order to retain a non-oxidized portion of the oxidizable layer 20′. Subsequent heat treatments carried out during phase 2 will tend to prolong oxygen diffusion from the thin oxidized layer 20 towards the interface with the substrate 10. This oxygen diffusion phenomenon, subsequent to phase 1, may thus be integrated into the decision regarding the thermal budget for oxidizing the thin layer 20′ of the phase 1 by retaining a non-oxidized thickness.

To improve the barrier effect of oxygen diffusion procured by the thin oxide layer 20 during the second thermal oxidation (of phase 2), the oxidizing gas may optionally be supplemented by a gaseous nitrogen oxide (NO or N₂O) to incorporate nitrogen into the thin elemental insulating layer 20. This technique allows a limited (1.5% to 2%) but homogeneous degree of incorporation into the oxide, as described by S. Wolf et al in “Silicon processing for the VLSI era” (Vol 1 “Process Technology, Lattice Press, USA, 2^{nd} edition (2000)).

Referring now to FIGS. 4 and 5, a (thicker) oxide layer is then constituted on the thin elemental insulating layer 20. A first operation consists in constituting an oxidizable layer 30′ of semiconductor material on the thin oxide layer 20. Subsequent to the formation of an oxidizable layer 30′, suitable cleaning and/or suitable surface treatment is advantageously carried out to prepare the surface of the layer 20. The oxidizable layer 30′ may be constituted by silicon, which may be crystalline or amorphous, and is deposited by epitaxy techniques which are known per se, such as CVD techniques. The temperature selected to produce the oxidizable layer 30′ is advantageously below the temperature above which a material of the substrate 10 would become unstable. As an example, if the substrate 10 contains Ge, the temperature must not exceed about 650° C.

The thickness selected for the oxidizable layer 30′ may be less than the limiting thickness beyond which oxidation departs from the linear region (as discussed above). In the case of silicon, then, a layer may be formed with thickness, for example, in the range about 20 nm to about 50 nm, depending on the envisaged oxidation temperature. Thus, for example, about 20 nm of Si may be formed to constitute about 40 nm of oxide at an oxidation temperature of about 800° C. for about ten hours. Moreover, for example, about 50 nm of Si may be formed to constitute about 100 nm of oxide at an oxidation temperature of about 900° C. for the same duration.

In the particular case in which an oxidizable layer 30′ is formed from amorphous silicon, an LPCVD technique may be used (starting from TEOS or silane/oxygen precursors) for a substrate temperature in the range from about 500° C. to about 600° C., and in particular in the range from about 550° C. to about 580° C. Preferably, a temperature of 600° C. is not exceeded, to avoid crystallization of the amorphous phase.

It should be noted that a subjacent surface (i.e. the thin oxide layer 20), which is amorphous, encourages the amorphous nature of the deposition phase and also reduces the chances of partial crystallization during subsequent heat treatments.

Thus, an amorphous phase is preferred to a polycrystalline phase in the context of the invention, the amorphous phase allowing better homogeneity of the surface and bulk of the deposited layer, which will render the oxidation front more homogeneous. As an example, the rate of wet thermal oxidation on a monocrystalline substrate has been measured at 5 Å/h for a [100] substrate and between 7 Å/h and 8 Å/h if the substrate is [111] (“Semiconductor devices”, S M Sze, John Wiley and Sons (NY), Inc, 2^{nd} Edition (2002)): oxidizing a polycrystalline layer will then be highly inhomogeneous.

Referring to FIG. 5, a second operation is carried out to oxidize the oxidizable layer 30′ in accordance with the invention, to constitute a second oxide layer 30. The surface may be polished before oxidation to further improve the homogeneity of the oxidation front. Oxidation is carried out with heat treatment in a dry or wet atmosphere. The oxidation temperature may then be selected to be between about 700° C. and about 800° C., provided that it does not exceed the thermal limits of certain materials of the substrate 10. The thermal oxidation may be carried out rapidly, given that precise control of the advance of the oxidation front may be lost due to the presence of the thin oxide layer 20 interfaced between the oxidizable layer 30′ and the substrate 10, which then protects the surface of the latter against too much oxygen diffusion.

As discussed above, the oxidation front of the thin oxide layer 20 may, however, advance during the second thermal oxidation step and perturb the subjacent crystalline layer. However, the “buried oxidation” from the thin oxide layer 20 is slow compared to that accompanying oxidizing the oxidizable layer 30′ which is fed from the surface. In order to anticipate this “buried oxidation” of phase 2, the prior oxidation of phase 1 is carried out so that the thin elemental oxidizable layer 20′ is not completely oxidized and leaves a thickness substantially equal to the thickness which is oxidized during the oxidation of phase 2. This thickness may be about 5 nm, for a thickness of the oxidizable layer 30′ of about 150 nm.

Finally, the structure 50 obtained is thus constituted by the starting substrate 10 and an oxide layer 40 which may be thick, constituted by the thin insulator elemental layer 20 and the thicker oxide layer 30, formation of these two layers having been implemented so that the final oxide layer 40 has a predetermined thickness.

In a variation of the invention, the phase 2 is repeated several times to form a stack of successive oxide layers each of thickness that is less than or equal to the limiting thickness beyond which oxidation would be outside the linear region. Thus, the successive oxidation steps carried out on the successively formed oxidizable layers all fall within the linear region. Thus, a final oxide layer 40 is obtained in a considerably shorter space of time than if it had been obtained from a single oxidizable layer 30′ (which would then have been oxidized in a non linear manner). Thus, a thicker oxide layer 40 is obtained within an industrially acceptable timeframe.

Once the oxide layer 40 has been formed, an additional step of planarization by chemical-mechanical polishing may optionally be carried out to improve the surface quality. The structure 50 of the invention may thus be used for bonding to an added substrate to produce the final structure. Bonding may primarily be carried out by molecular bonding, optionally aided by a prior step of hydrophilizing at least one of the two surfaces using chemical agents and/or a plasma treatment. Secondly, the bonds may be strengthened by suitable heat treatment(s).

After bonding, for example, the added substrate and/or the substrate 10 of the structure 50 may be reduced to produce a final semiconductor-on-insulator structure, the insulating portion being the oxide layer 40 formed in accordance with the invention. The great thickness of the oxide layer 40 endows the layer with very good dielectric properties, thereby improving the functions of electronic, optical, or optronic components to be provided in the semiconductor portion of the semiconductor-on-insulator structure.

The reduction of one of the two substrates or both substrates may be carried out by lapping then polishing, by chemical etching, using the SMART-CUT® technique which is known per se to the skilled person, or by using any other wafer reduction technique.

When using the SMART-CUT® technique prior to bonding, one (or both) of the two substrates has to be implanted with atomic species (such as hydrogen, helium or a combination of the two, or other atomic species) at an energy and dose selected to produce within its thickness a zone of weakness at a depth close to the thickness of the layer that is to be retained. In the case of implantation into the substrate 10, implantation may be carried out before forming the thin oxide layer 20 or between forming the thin oxide layer 20 and forming the oxide layer 30, or following formation of the oxide layer 30. Finally, once bonding has been carried out, supplying suitable thermal or mechanical energy can rupture bonds at the zone of weakness to detach a layer of the substrate under consideration and thus obtain the desired semiconductor-on-insulator structure.

The technique used in accordance with the invention can thus produce such structures comprising a thick thermal oxide layer 40 on a material which cannot tolerate thermal oxidation well, such as SiGe or Ge. The dielectric properties of the structure are thus even further improved because of the quality of a thermal oxide is better than that of a deposited oxide. From a morphological viewpoint, a thermal oxide is more homogeneous, denser, and less porous. From an electrical viewpoint, breakdown voltages are higher, and interface and bulk charges are generally lower.

Other constituents such as dopants, or carbon with a concentration of carbon in the layer under consideration which is substantially 50% or less or, more particularly, with a concentration of 5% or less, may be added to the substrate 10, to the thin layer 20′ and/or to the layer 30′.

Finally, the present invention is not limited to a substrate 10, a thin layer 20′ and/or a layer 30′ of IV or IV-IV materials as presented above, but also encompasses other types of materials belonging to atomic groups II, III, IV, V or VI and to alloys belonging to IV-IV, II-V, II-VI atomic groups. Further, the substrate 10 may comprise intermediate layers of non conducting or non semiconductor materials such as dielectric materials.

It should be pointed out that in the case of alloyed materials, the alloys selected may be binary, ternary, quaternary or of higher degree.

What is claimed is:

1. A method of forming an insulating layer on a structure of semiconductor material, which method comprises:
providing a thin elemental insulating layer at a mean thickness of 20 nm or less upon a substrate layer;
providing an oxidizable layer upon the insulating layer;
thermally oxidizing the oxidizable layer so that the combination of the oxidized oxidizable layer and the thin elemental insulating layer provides a desired thickness of the insulating layer of the structure.

2. The method of claim 1, wherein the thin elemental insulator layer is constituted by depositing an oxide or silicon nitride and the oxidiziable layer has a thickness of about 50 nm to about 100 nm.

3. The method of claim 2, wherein the thin elemental insulator layer which is deposited does not exceed 10% of the total thickness of the insulating layer that is formed.

4. The method of claim 1, wherein the substrate layer is covered with a thin elemental oxidizable layer, and wherein the thin elemental insulator layer is produced by thermal oxidation of a portion of the thin elemental oxidizable layer at an oxidation temperature which is sufficiently low for not substantially altering the intrinsic properties of the material constituting the substrate layer.

5. The method of claim 4, wherein the oxidation temperature of the thin oxidizable layer is in a temperature range of about 500° C. (932° F.) to about 900° C. (1652° F.).

6. The method of claim 4, wherein the oxidizing of the thin elemental oxidizable layer is processed from a gaseous oxide of nitrogen in addition to oxygen.

7. The method of claim 6, wherein the oxidizing of the thin elemental oxidizable layer is carried out to incorporate therein 1.5% to 2% of nitrogen.

8. The method of claim 4, further comprising epitaxy of the thin elemental oxidizable layer for covering the substrate layer.

9. The method of claim 8, wherein epitaxy of the thin elemental oxidizable layer is carried out in situ following epitaxy of the surface layer of the substrate layer.

10. The method of claim 4, wherein the thin elemental oxidizable layer is constituted by the same material as that constituting the surface of the substrate layer.

11. The method of claim 4, wherein the thin elemental oxidizable layer is formed from silicon or amorphous silicon.

12. The method of claim 1, wherein the substrate layer comprises or is formed form a surface of Si₁₋ₓGeₓ, with x in the range from 0 (included) to 1 (included).

13. The method of claim 1, wherein the oxidizable layer constituted during step b) is formed from silicon or amorphous silicon.

14. The method of claim 1, wherein the oxidizable layer is to have a final thickness of about 20 nm to about 100 nm.

15. The method of claim 1, wherein the oxidizable layer is produced by LPCVD at a temperature between about 550° C. (1022° F.) and about 580° C. (1076° F.).

16. The method of claim 15, wherein the oxidation temperature is in the range of about 700° C. (1292° F.) to about 800° C. (1472° F.).

17. The method of claim 1, wherein the providing of the oxidizable layer upon the insulating layer and the thermally oxidizing of the oxidizable layer are repeated in succession in a desired number of times.

18. The method of claim 1, further comprising, after the step of creating the insulating layer of the structure, a step of covering the insulating layer with a covering layer, the insulating layer thereby being buried in the structure.
